(19) United States
(12) Patent Application Publication
(10) Pub. No.: US 2026/0150748 A1
(43) Pub. Date: May 28, 2026

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Chih-Chien Pan, Taipei City (TW); Chien-Chang Lin, New Taipei City (TW); Li-Hui Cheng, New Taipei City (TW)

(73) Assignee: Taiwan Semiconductor Manufacturing Company, Ltd., Hsinchu (TW)

(21) Appl. No.: 18/963,423

(22) Filed: Nov. 27, 2024

(51) Int. Cl. H01L 23/18; H01L 21/56; H01L 23/00; H01L 23/04; H01L 23/48; H01L 23/498; H01L 25/18; H10B 80/00

(52) U.S. Cl. CPC H10W 76/42; H10W 74/014; H10W 74/016; H10W 76/12; H10W 90/00; H10B 80/00; H10W 20/20; H10W 42/121; H10W 70/685; H10W 72/0198; H10W 72/227; H10W 72/325; H10W 72/353; H10W 72/354; H10W 72/357; H10W 72/877; H10W 74/15; H10W 80/312; H10W 80/327; H10W 90/724; H10W 90/734; H10W 90/794

(57) ABSTRACT

A semiconductor package includes a substrate, a first semiconductor device disposed over the substrate, a plurality of second semiconductor devices disposed over the substrate and around the first semiconductor device, a ring structure disposed over the substrate, and a lid structure. The ring structure surrounds the first semiconductor device and the plurality of second semiconductor devices, and disposed between the first semiconductor device and the plurality of second semiconductor devices, the ring structure includes a flange portion partially overlap with top surfaces of the plurality of second semiconductor devices from a top view. The lid structure covers and is bonded to the first semiconductor device, the plurality of second semiconductor devices and an upper surface of the flange portion.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 11 illustrate cross sectional views of intermediate stages in the manufacturing of a semiconductor package according to some embodiments of the present disclosure.

FIG. 12 illustrates a perspective top view of the semiconductor package at an intermediate stage of the manufacturing process according to some embodiments of the present disclosure.

FIG. 13 illustrates a partial enlarged view of the semiconductor package according to some embodiments of the present disclosure.

FIG. 14 illustrates a schematic cross sectional view of the semiconductor package according to some embodiments of the present disclosure.

FIG. 15 to FIG. 22 illustrate cross sectional views of intermediate stages in the manufacturing of a semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments disclosed herein relate generally to packages with a ring structure surrounding first dies (e.g., higher power consuming dies such as logic dies) and second dies (e.g., lower power consuming dies such as memory dies) and a lid structure covering and bonded to the first dies, the second dies, and the ring structure. The ring structure includes a flange portion partially overlapping with the top surfaces of the second dies from a top view such that the adhesive is disposed between the overlapping region of the flange portion and the second dies and the overlapping region of the flange portion and the lid structure. Accordingly, the bonding strength between the ring portion and the lid portion and the dies are enhanced. In addition, a thermal interface material may be dispensed on the first dies for bonding the lid structure to the first dies. According to the embodiments of the disclosure, a thermal interface material that has a relatively high thermal conductivity is dispensed on a high-power consuming die or die stack. Therefore, the heat dissipation of the whole package is improved.

The foregoing broadly outlines some aspects of the embodiments described herein. Some embodiments described herein are described in the context of 3D IC packages or 2.5D IC packages. Some variations of the exemplary methods and structures are described in the embodiments of the disclosure. A person having ordinary skill in the art will readily understand other modifications may be made that are contemplated within the scope of other embodiments. Although embodiments of the method may be described in a particular order, various other embodiments of the method may be performed in any logical order and may include fewer or more steps than what is described herein.

In one embodiment, the semiconductor package may include a System on Integrate Chip (SoIC) package. The intermediate stages of forming the packages are illustrated in accordance with some embodiments. Some variations of some embodiments are discussed. Throughout the various views and illustrative embodiments, like reference numbers are used to designate like elements.

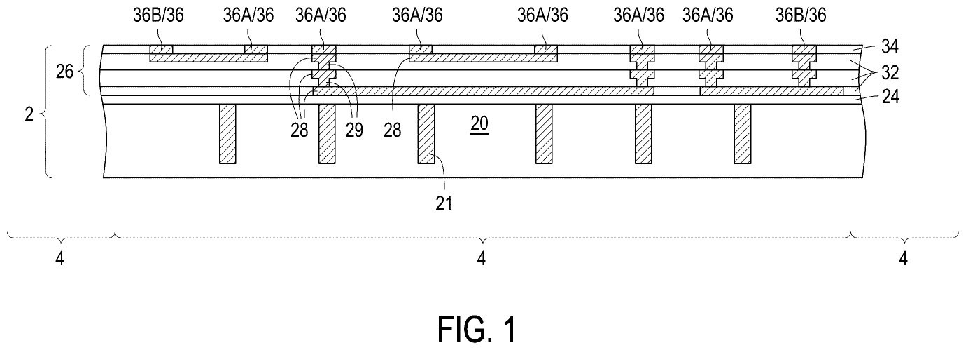

FIG. 1 to FIG. 11 illustrate cross sectional views of intermediate stages in the manufacturing of a semiconductor package according to some embodiments of the present disclosure. FIG. 1 illustrates the cross-sectional view in the formation of a wafer 2. In accordance with some embodiments of the present disclosure, the wafer 2 is an interposer wafer, which is free from any active devices such as transistors and/or diodes therein. In accordance with some embodiments of the present disclosure, the interposer wafer 2 is also free from passive devices such as capacitors, inductors, resistors, or the like therein. In some embodiments, the interposer wafer 2 may include a plurality of metal lines and vias therein, with some details of one of a plurality of interposer dies 4 illustrated schematically. The interposer dies 4 are alternatively referred to as interposers or chips hereinafter. The interposer dies 4 are used for routing, as will be discussed in subsequent paragraphs.

The wafer 2 may include a substrate 20 and the features over the top surface of the substrate 20. In accordance with some embodiments of the present disclosure, the substrate 20 is a semiconductor substrate. The substrate 20 may be formed of crystalline silicon, crystalline germanium, crystalline silicon germanium, and/or a III-V compound semiconductor such as GaAsP, AlInAs, AlGaAs, GaInAs, GaInP, GaInAsP, or the like. The semiconductor substrate 20 may also be a bulk silicon substrate or a silicon-on-insulator (SOI) substrate. In accordance with some embodiments in which the substrate 20 is a semiconductor substrate, shallow trench isolation (STI) regions (not shown) may be formed in the substrate 20 to isolate the regions in the substrate 20. In accordance with alternative embodiments, STI regions are not formed in the wafer 2 since the wafer 2 does not have active devices, and hence does not need STI regions to isolation active regions from each other. The substrate 20 may also be a dielectric substrate, which may be formed of silicon oxide, for example. In accordance with some embodiments, the wafer 2 may be a device wafer, which includes a plurality of device dies 4 therein. In accordance with some embodiments, the device dies 4 include active circuits, which include active devices such as transistors (not shown) formed at the top surface of the semiconductor substrate 20.

In accordance with some embodiments, a plurality of through vias 21 are formed to extend into the semiconductor substrate 20, wherein the through-vias are used to electrically inter-couple the features on opposite sides of the semiconductor substrate 20. The through vias 21 are also sometimes referred to as through substrate vias or through silicon vias when substrate 20 is a silicon substrate. The through vias 21 may be formed by forming recesses in the substrate 20 by, for example, etching, milling, laser techniques, a combination thereof, and/or the like. A thin dielectric material may be formed in the recesses, such as by using an oxidation technique. A thin barrier layer may be conformally deposited over the front side of the substrate 20 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 20 by, for example, CMP. Thus, the through vias 21 may include a conductive material and a thin barrier layer between the conductive material and the substrate 20. In accordance with alternative embodiments, no through-vias are formed extending into the semiconductor substrate 20.

In accordance with some embodiments, at least one dielectric layer 24 may be formed over the substrate 20. In accordance with some embodiments of the present disclosure, the dielectric layer 24 is an Inter-Layer Dielectric (ILD), which may be formed of silicon oxide, Phospho Silicate Glass (PSG), Boro Silicate Glass (BSG), Boron-Doped Phospho Silicate Glass (BPSG), Fluorine-Doped Silicate Glass (FSG), Tetra Ethyl Ortho Silicate (TEOS), or the like. The dielectric layer 24 may be formed using thermal oxidation, spin coating, Flowable Chemical Vapor Deposition (FCVD), Atomic Layer Deposition (ALD), Chemical Vapor Deposition (CVD), Plasma Enhanced Chemical Vapor Deposition (PECVD), Low Pressure Chemical Vapor Deposition (LPCVD), or the like.

Over the dielectric layer 24 resides interconnect structure 26. Interconnect structure 26 includes metal lines 28 and vias 29, which are formed in the dielectric layers 32. The dielectric layers 32 are alternatively referred to as Inter-Metal Dielectric (IMD) layers hereinafter. In accordance with some embodiments of the present disclosure, the dielectric layers 32 are formed of low-k dielectric materials having dielectric constants (k-values) lower than 3.8. For example, the k values of the dielectric layers 32 may be lower about 3.0 or lower than about 2.5. The dielectric layers 32 may be formed of Black Diamond (a registered trademark of Applied Materials), a carbon-containing low-k dielectric material, Hydrogen SilsesQuioxane (HSQ), MethylSilsesQuioxane (MSQ), or the like. In accordance with alternative embodiments of the present disclosure, some or all of the dielectric layers 32 are formed of non-low-k dielectric materials such as silicon oxide, silicon carbide (SiC), silicon carbo-nitride (SiCN), silicon oxy-carbo-nitride (SiOCN), or the like. In accordance with some embodiments of the present disclosure, the formation of the dielectric layers 32 includes depositing a porogen-containing dielectric material, and then performing a curing process to drive out the porogen, and hence the remaining dielectric layers 32 is porous. Etch stop layers (not shown), which may be formed of silicon carbide, silicon nitride, or the like, are formed between the dielectric layers 32, and are not shown for simplicity.

A plurality of metal lines 28 and vias 29 are formed in the dielectric layers 32. The metal lines 28 at a same level are collectively referred to as a metal layer hereinafter. In accordance with some embodiments of the present disclosure, interconnect structure 26 includes a plurality of metal layers that are interconnected through vias 29. The metal lines 28 and vias 29 may be formed of copper or copper alloys, and they can also be formed of other metals. The formation process may include single damascene and dual damascene processes. In a single damascene process, a trench is first formed in one of the dielectric layers 32, followed by filling the trench with a conductive material. A planarization process such as a CMP process is then performed to remove the excess portions of the conductive material higher than the top surface of the IMD layer, leaving a metal line in the trench. In a dual damascene process, both a trench and a via opening are formed in an IMD layer, with the via opening underlying and in spatial communication with the trench. The conductive material is then filled into the trench and the via opening to form a metal line and a via, respectively. The conductive material may include a diffusion barrier layer lining the trench and the via and a copper-containing metallic material over the diffusion barrier layer. The diffusion barrier layer may include titanium, titanium nitride, tantalum, tantalum nitride, or the like.

Then, a surface dielectric layer 34 is formed of a non-low-k dielectric material such as silicon oxide. The surface dielectric layer 34 is alternatively referred to as a passivation layer since it has the function of isolating the underlying low-k dielectric layers (if any) from the adverse effect of detrimental chemicals and moisture. The surface dielectric layer 34 may also have a composite structure including more than one layer, which may be formed of silicon oxide, silicon nitride, Undoped Silicate Glass (USG), or the like. Interposer dies 4 may also include metal pads underlying the surface dielectric layer 34, and the metal pads may include aluminum or aluminum copper pads, Post-Passivation Interconnect (PPI), or the like, which are not shown for simplicity.

Then, a plurality of bond pads 36A and 36B, which are also collectively and individually referred to the bond pads 36, are formed in the surface dielectric layer 34. In accordance with some embodiments of the present disclosure, the bond pads 36A and 36B are formed through a single damascene process, and may also include barrier layers and a copper-containing material formed over the barrier layers. In accordance with alternative embodiments of the present disclosure, the bond pads 36A and 36B are formed through a dual damascene process. Some of the bond pads 36A may be electrically coupled to other bond pads 36A and 36B through the metal lines 28 and vias 29. In accordance with some embodiments of the present disclosure, each of the bond pads 36A and bond pads 36B is electrically connected to at least one (or more) of other bond pads 36A and 36B through metal lines 28 and vias 29, and none of the bond pads 36A and 36B is electrically disconnected to all other bond pads 36A and 36B.

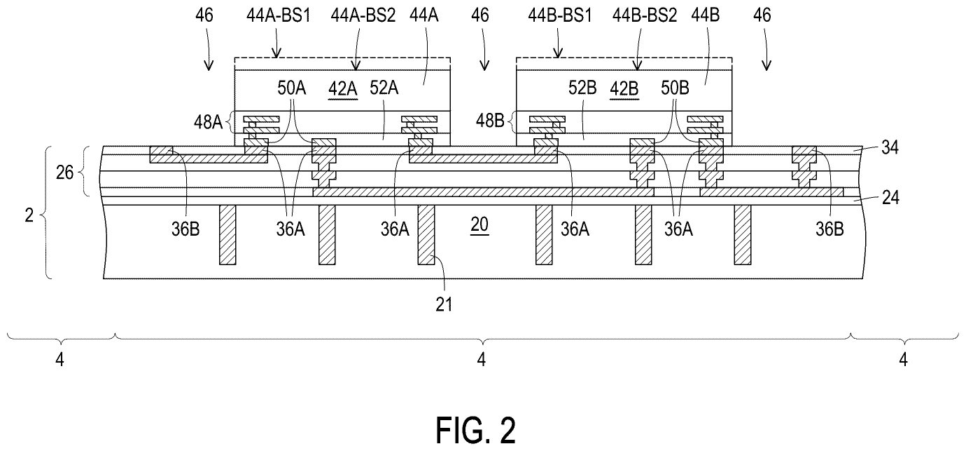

Next, referring to FIG. 2, at least one device die is bonded to the wafer 2. In the present embodiment, a plurality of device dies (e.g., first dies) 42A and 42B are bonded to the wafer 2, as shown in FIG. 2, and the number of the device dies is not limited thereto. In some embodiments, the device dies 42A and 42B may be a single System on a Chip (SoC) die, multiple SoC stacked dies, or the like. One or each of the device dies 42A and 42B may also be a Central Processing Unit (CPU) die, a Micro Control Unit (MCU) die, an input-output (IO) die, a BaseBand (BB) die, or an Application processor (AP) die. The device dies 42A and 42B may be the same type or different types of dies selected from the above-listed types. In one embodiment, one of the device dies 42A and 42B may be a memory die such as Dynamic Random Access Memory (DRAM) dies or Static Random Access Memory (SRAM) dies. The device dies 42A and 42B in combination function as a package.

The device dies 42A and 42B include substrates 44A and 44B, respectively, which may be semiconductor substrates such as silicon substrates. In accordance with some embodiments, the substrates 44A and 44B are also referred to as semiconductor substrates 44A and 44B. In accordance with some embodiments of the present disclosure, the device dies 42A and 42B may be free from through silicon vias (TSVs) therein. Also, the device dies 42A and 42B include interconnect structures 48A and 48B, respectively, for connecting to the active devices and passive devices in the device dies 42A and 42B. The interconnect structures 48A and 48B include metal lines and vias, which are illustrated schematically. In some embodiments, the substrates 44A and 44B may be free from through-vias therein. Accordingly, all external electrical connections of the device dies 42A and 42B are made through the bond pads 50A and 50B.

In some embodiments, the device die 42A includes a plurality of bond pads 50A and dielectric layer 52A at the illustrated bottom surface. The bottom surfaces of bond pads 50A are coplanar with the bottom surface of dielectric layer 52A. Similarly, the device die 42B includes a plurality of bond pads 50B and dielectric layer 52B at the illustrated bottom surface. The bottom surfaces of the bond pads 50B are coplanar with the bottom surface of dielectric layer 52B.

The bonding of the device dies 42A and 42B to wafer 2 may be achieved through hybrid bonding. For example, the bond pads 50A and 50B are bonded to the bond pads 36A through direct metal bonding (i.e., metal-to-metal direct bonding). In accordance with some embodiments of the present disclosure, the metal-to-metal direct bonding is copper-to-copper direct bonding. Furthermore, the dielectric layers 52A and 52B are bonded to the surface dielectric layer 34, for example, with fusion bonds (which may include Si—O—Si bonds) generated.

To achieve the hybrid bonding, the device dies 42A and 42B are first pre-bonded to the surface dielectric layer 34 and the bond pads 36A by lightly pressing the device dies 42A and 42B against the interposer die 4. Although two device dies 42A and 42B are illustrated, the hybrid bonding may be performed at wafer level, and a plurality of device die groups identical to the illustrated die group including device dies 42A and 42B is pre-bonded, and arranged as rows and columns.

After all device dies 42A and 42B are pre-bonded, an anneal process is performed to cause the inter-diffusion of the metals in the bond pads 36A and the corresponding overlying bond pads 50A and 50B. The annealing temperature may be in the range between about 200° and about 400° C., and may be in the range between about 300° and about 400° C. in accordance with some embodiments. The annealing time is in the range between about 1.5 hours and about 3.0 hours, and may be in the range between about 1.5 hours and about 2.5 hours in accordance with some embodiments. Through the hybrid bonding, the bond pads 50A and 50B are bonded to the corresponding bond pads 36A through direct metal bonding caused by metal inter-diffusion.

The surface dielectric layer 34 is also bonded to dielectric layers 52A and 52B, with bonds formed therebetween. For example, the atoms (such as oxygen atoms) in one of the surface dielectric layer 34 and the dielectric layers 52A/52B form chemical or covalence bonds with the atoms (such as silicon atoms) in the other one of the surface dielectric layers 34 and the dielectric layer 52A/52B. The resulting bonds between the surface dielectric layers 34 and the dielectric layer 52A/52B are dielectric-to-dielectric bonds. The bond pads 50A and 50B may have sizes greater than, equal to, or smaller than, the sizes of the respective bond pads 36A. The gaps 46 are left between neighboring device dies 42A and 42B.

Further referring to FIG. 2, a backside grinding may be performed to thin the device dies 42A and 42B, for example, to a thickness between about 15 μm and about 30 μm. FIG. 2 schematically illustrates dashed lines 44A-BS1 and 44B-BS1, which are the back surfaces of the device dies 42A and 42B, respectively before the backside grinding. Solid lines 44A-BS2 and 44B-BS2 are the back surfaces of device dies 42A and 42B, respectively after the backside grinding. Through the thinning of the device dies 42A and 42B, the aspect ratio of gaps 46 between neighboring device dies 42A and 42B is reduced. Otherwise, the gap-filling may be difficult due to the otherwise high aspect ratio of gaps 46. In accordance with other embodiments in which the aspect ratio of gaps 46 is not too high for gap filling, the backside grinding is skipped.

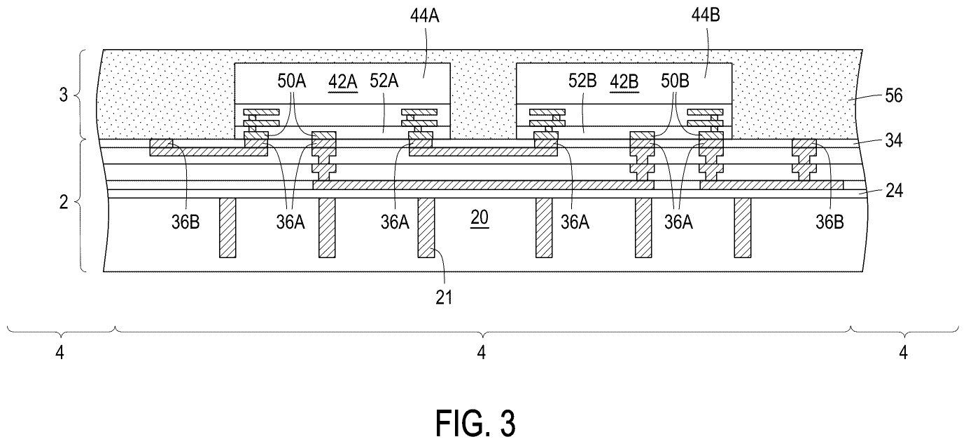

Then, referring to FIG. 3, in accordance with some embodiments of the present disclosure, an encapsulating material 56 is formed over the wafer 2. The encapsulating material 56 at least laterally encapsulates the device dies 42A and 42B. The encapsulating material 56 includes dielectric material, which may be deposited using a conformal deposition method such as Atomic Layer Deposition (ALD) or Chemical Vapor Deposition (CVD), or a non-conformal deposition method such as High-Density Plasma Chemical Vapor Deposition (HDPCVD), Flowable Chemical Vapor Deposition (CVD), spin-on coating, or the like.

In some embodiments, the encapsulating material 56 may be formed of an inorganic dielectric material. In accordance with some embodiments of the present disclosure, the encapsulating material 56 includes an oxide such as silicon oxide, which may be formed of TEOS, while other dielectric materials such as silicon carbide, silicon oxynitride, silicon oxy-carbo-nitride, or the like may also be used. The encapsulating material 56 fully fills gaps 46 (FIG. 2), and further includes some portions overlapping device dies 42A and 42B. The encapsulating material 56 may be formed of a non-conformal formation method or a conformal formation method.

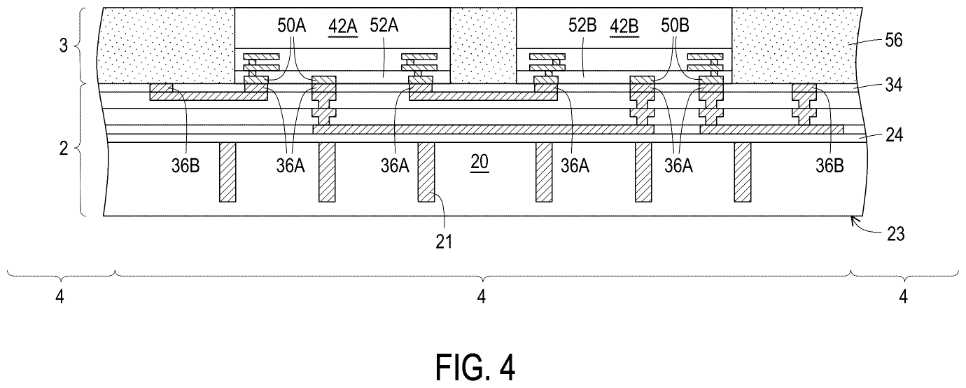

Then, referring to FIG. 4, a planarization process such as a CMP process or a mechanical grinding process is performed to remove the excess portions of the encapsulating material 56. In accordance with some embodiments of the present disclosure, the planarization is stopped when there is a layer of the encapsulating material 56 overlapping the device dies 42A and 42B. As a result, after the planarization process, the substrates 44A of the device die 42A and the substrate 44B of the device die 42B are exposed, and the exposed back surfaces of the device dies 42A and 42B are substantially coplanar with the top surface of the encapsulating material 56. At the time, a reconstructed wafer 3 over the wafer 2 is formed.

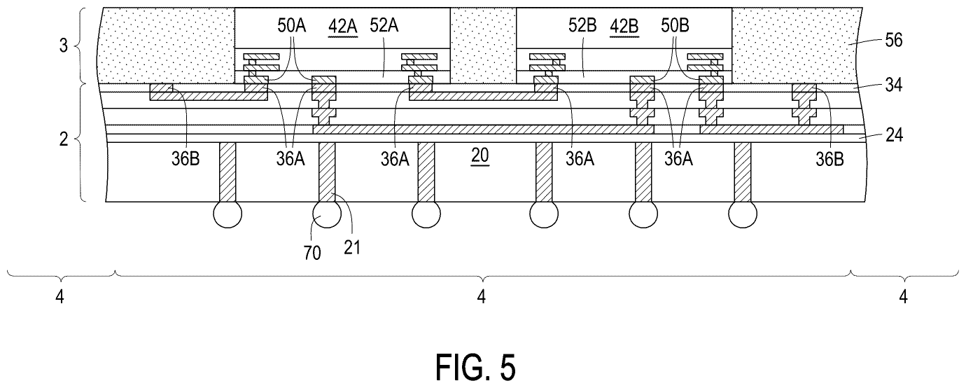

Then, referring to FIG. 5, a thinning process is performed on a back side 23 of the substrate 20 to thin the substrate 20 until the through vias 21 are exposed. In detail, the structure of FIG. 4 may be flipped over to prepare for the formation of the back side 23 of the wafer 2. Although not shown, the structure may be placed on a carrier or support structure for the process of FIG. 5. The thinning process may include an etching process, a grinding process, the like, or a combination thereof.

A redistribution structure (not shown) may be formed on the back side 23 of the substrate 20, and is used to electrically connect the through vias 21 together and/or to external devices. The redistribution structure includes one or more dielectric layers and metallization patterns in the one or more dielectric layers. The metallization patterns may comprise vias and/or traces to interconnect the through vias 21 together and/or to an external device. The metallization patterns are sometimes referred to as Redistribution Lines (RDLs). The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. The metallization patterns may be formed in the dielectric layer, for example, by using photolithography techniques to deposit and pattern a photoresist material on the dielectric layer to expose portions of the dielectric layer that are to become the metallization pattern.

In FIG. 5, a plurality of conductive connectors 70 are formed over the redistribution structure and are electrically coupled to the through vias 21. In some embodiments, the metallization patterns include UBMs. In the illustrated embodiment, the pads are formed in openings of the dielectric layers of the redistribution structure. In another embodiment, the pads (UBMs) can extend through an opening of a dielectric layer of the redistribution structure and also extend across the top surface of the redistribution structure.

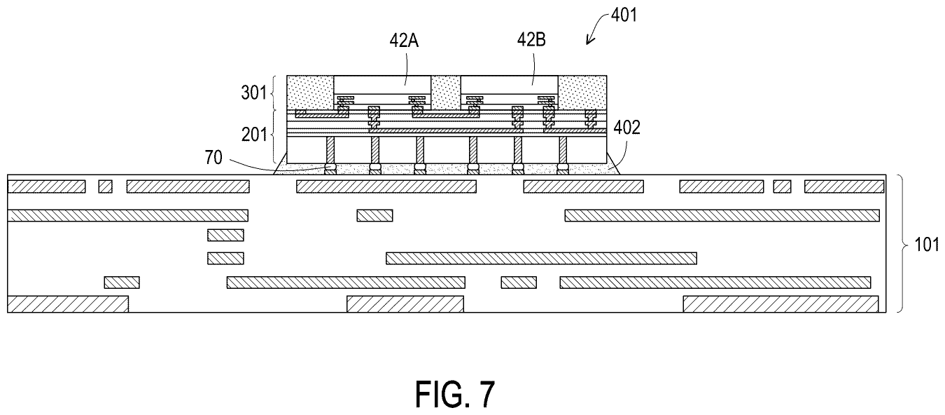

In some embodiments, the conductive connectors 70 are solder balls and/or bumps, such as ball grid array (BGA) balls, C4 micro bumps, ENIG formed bumps, ENEPIG formed bumps, or the like. The conductive connectors 70 may include a conductive material such as solder, copper, aluminum, gold, nickel, silver, palladium, tin, the like, or a combination thereof. In some embodiments, the conductive connectors 70 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 70 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 70. The metal cap layer may include nickel, tin, tin-lead, gold, silver, palladium, indium, nickel-palladium-gold, nickel-gold, the like, or a combination thereof and may be formed by a plating process. The conductive connectors 70 may be used to bond to an additional electrical component, which may be a semiconductor substrate, a package substrate, a Printed Circuit Board (PCB), or the like (see substrate 101 in FIG. 7).

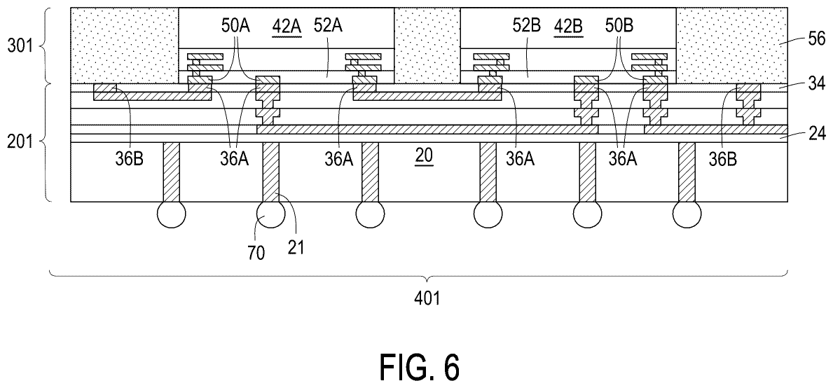

Throughout the description, the structure shown in FIG. 5 is referred to as composite wafer, which includes a reconstructed wafer 3 bonded over the wafer 2. Then, referring to FIG. 6, a singulation (die-saw) process is performed on composite wafer shown in FIG. 5 to separate the composite wafer into a plurality of (first) semiconductor devices 401. One of the (first) semiconductor devices 401 is illustrated in FIG. 6. In some embodiments, the (first) semiconductor device 401 is a die stack structure, which includes a lower die 201, and an upper die 301 stacked over and bonded to the lower die 201. The singulation process may include sawing, dicing, or the like. To be more specific, the singulation process is performed on the encapsulating material 56 and the wafer 2 to separate the composite wafer into a plurality of die stack structures 401. After the singulation process, the lower die 201 is singulated from the interposer wafer 2 to be functioned as an interposer, and the upper die 301 is singulated from the reconstructed wafer 3 and the first dies 42A and 42B in the upper die 301 is bonded to the interposer 201 through hybrid bonding. That is, the first dies 42A and 42B of the upper die 301 includes a plurality of upper pads 50A and 50B are in direct contact (bonding) with a plurality of lower pads 36A and 36B of the lower die 201 respectively. In the embodiment, the upper die 301 includes the device die 42A and 42B encapsulated by the encapsulating material 56. In other embodiment, the lower die 201 and the lower die 301 may both be device dies and directly bonded to the each other through hybrid bonding. The disclosure is not limited thereto.

FIG. 7 illustrates the bonding of the first semiconductor device (package structure) 401 onto a substrate 101. Referring to FIG. 6 and FIG. 7, the conductive connectors 70 are aligned to, and are put against, the bond pads of the substrate 101. The conductive connectors 70 may be reflowed to create a bond between the substrate 101 and the first semiconductor device 401. The substrate 101 may include a package substrate, such as a build-up substrate including a core therein, a laminate substrate including a plurality of laminated dielectric films, a PCB, or the like. The substrate 101 may include electrical connectors (not shown), such as solder balls, opposite the component package to allow the substrate 101 to be mounted to another device. In the first semiconductor device 401, the lower die 201 is bonded to the substrate 300 through the conductive connectors 70 and a plurality of dies 42A and 42B are stacked over and bonded to the lower die 201 through, for example, hybrid bonding (e.g., fusion bonding and direct metal bonding). That is, there is no conductive connectors between the lower die 201 and upper die 301(including dies 42A and 42B), and the pads 50A and 50B of the dies 42A and 42B are in direct contact with the pads 36A of the lower die 201. The encapsulating material 56 is disposed over the lower die 201 and laterally encapsulating the dies 42A and 42B. An underfill material 402 may be provided between the first semiconductor device 401 and the substrate 101 and encapsulate the conductive connectors 70.

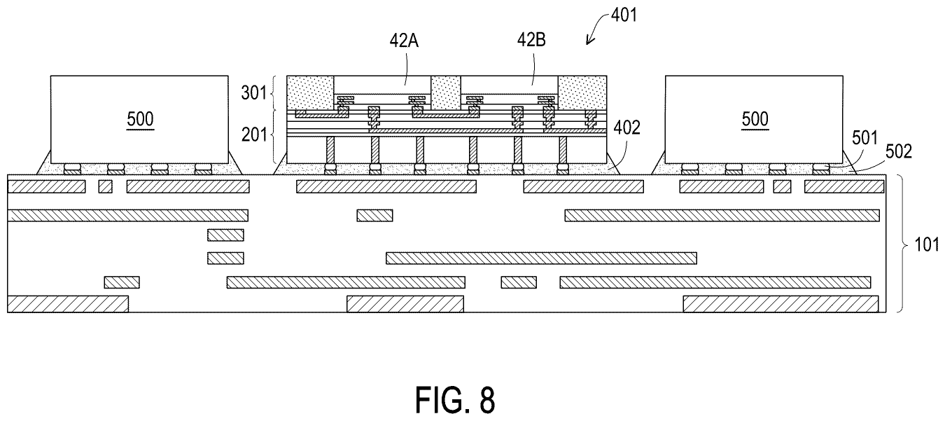

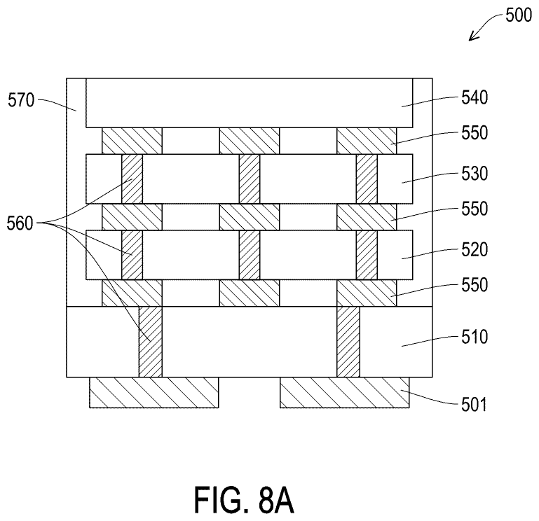

FIG. 8A illustrates a schematic cross sectional view of one of the second semiconductor devices according to some embodiments of the disclosure. Referring to FIG. 8 and FIG. 8A, then, a plurality of second semiconductor devices 500 are disposed over the substrate 101 and arranged around the first semiconductor devices 401. In some embodiments, each of the semiconductor devices 500 may be a semiconductor die or a semiconductor package. In some embodiments, as shown in FIG. 8A, each of the second semiconductor devices 500 may be a die stack. In the embodiment, each of the second semiconductor devices 500 is a memory die stack, which includes multiple stacked memory dies 520, 530, 540 bonded to a logic die 510 (sometimes called a base die or a buffer die). Each of the memory dies 520, 530, 540 may include a static random access memory (SRAM) device, a dynamic random access memory (DRAM) device, a high bandwidth memory (HBM) device, or another type of memory device. The number of memory dies 520, 530, 540 are not limited to three, and the number can be adjusted according to actual application. The memory dies 520, 530, 540 may be bonded to each other by a number of bonding structures 550. A number of through substrate vias 560 may be formed in the memory dies 520, 530, 540. The signal between the memory dies 520, 530, 540 may be transferred through the through substrate vias 560 and the bonding structures 550. A protective layer 570 made of molding material (such as an epoxy-based resin) may also be formed to surround and protect the logic die 510 and the memory dies 520, 530, 540, in accordance with some embodiments.

In some embodiments, the second semiconductor devices 500 are bonded to the substrate through a plurality of conductive connectors 501. An underfill material 502 may be provided between the second semiconductor devices 500 and the substrate 101 and encapsulate the conductive connectors 501. Each of the second semiconductor devices 500 may include a plurality of conductive pads, which are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive pad may be formed by an electroplating, electroless plating, printing, a chemical vapor deposition (CVD) process, or a physical vapor deposition (PVD) process. The conductive connector 501 is made of solder materials, such as tin (Sn), SnAg, SnPb, SnAgCu, SnAgZn, SnZn, SnBiIn, SnIn, SnAu, SnPb, SnCu, SnZnIn, SnAgSb or another applicable material. In some embodiments, the conductive connector 501 is formed by electroplating, electroless plating, printing, a chemical vapor deposition (CVD) process, or a physical vapor deposition (PVD) process.

In some embodiments, at least one first semiconductor device 401 and a plurality of second semiconductor devices 500 around the first semiconductor device 401 are disposed on the substrate 101. In fact, any number of dies, packages and/or die stacks may be disposed on the substrate 101, and is not limited to the number of dies and/or die stacks in FIG. 8. In addition, the layout of the dies and/or die stacks on the substrate is not limited to that of FIG. 8.

In accordance with some embodiments, a plurality of second semiconductor devices (e.g., die stacks) 500 are arranged on two opposite sides of the first semiconductor device (e.g., package structure) 401. In some embodiments, the first semiconductor device 401 includes at least one high-power consuming die (e.g., first dies 42A and 42B) and the second semiconductor devices 500 are low-power consuming die stacks. The first semiconductor device 401 may consume a relatively high amount of power, and hence generate a relatively large amount of heat, compared to the second semiconductor devices 500.

In some embodiments, the first dies 42A and 42B of the first semiconductor device 401 may be a single system on chip (SoC) die or a logic die, which may further be a Central Processing Unit (CPU), a Graphics Processing Unit (GPU), or the like. In some embodiments, the dies of second semiconductor devices 500 may be high bandwidth memory (HBM) and/or high memory cube (HMC) modules, which may include multiple memory dies 520, 530, 540 bonded to a logic die 510, as shown in FIG. 8A in accordance with some embodiments. In alternative embodiments, the first semiconductor device 401 and the second semiconductor devices 500 may be other chips having other functions.

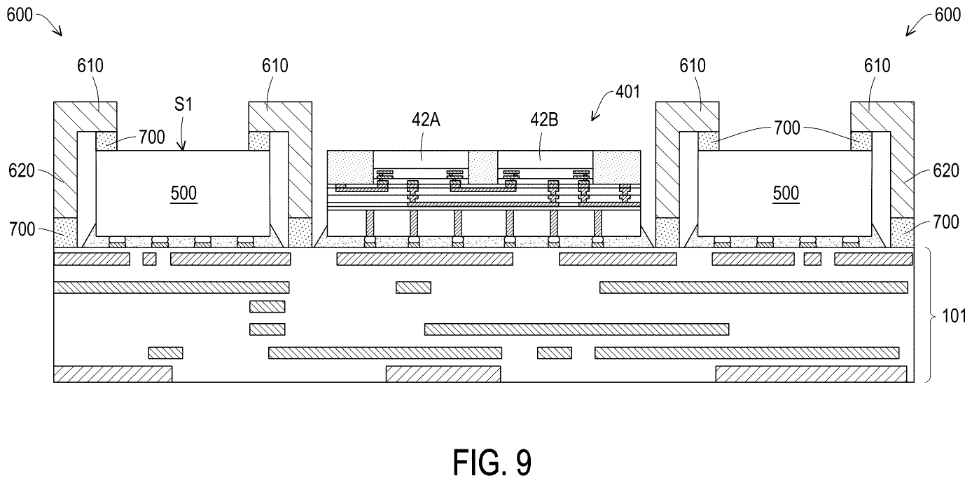

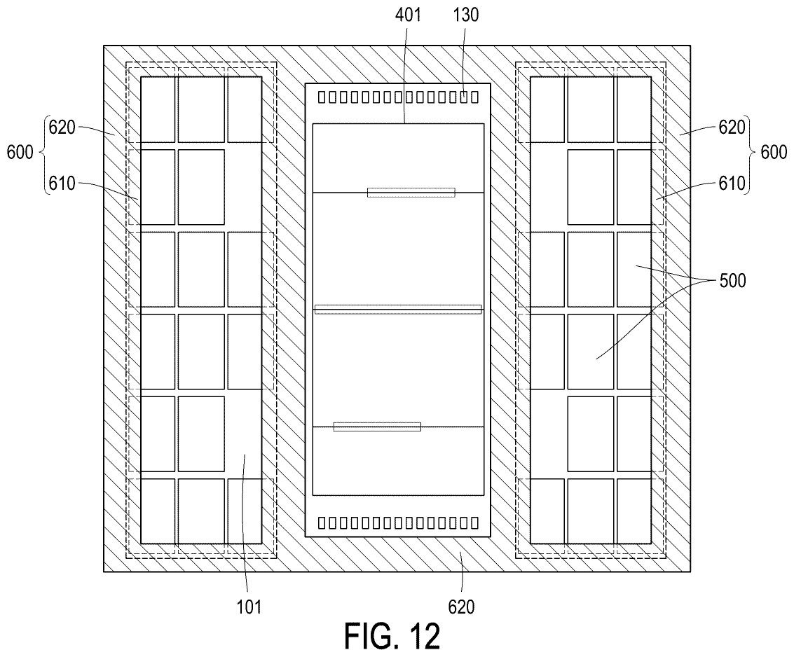

FIG. 12 illustrates a perspective top view of the semiconductor package at an intermediate stage of the manufacturing process according to some embodiments of the present disclosure. It is noted that FIG. 12 merely illustrates one of the possible layout of the first semiconductor device 401 and the second semiconductor devices 500, and the numbers of the second semiconductor devices 500 shown in FIG. 12 and the numbers of the second semiconductor devices 500 shown in FIG. 9 are different, but can all be applied to the present disclosure. Referring to FIG. 9 and FIG. 12, an adhesive 700 is provided on the substrate 101 and top surfaces S1 of the second semiconductor devices 500. In some embodiments, the adhesive 700 is dispensed on a peripheral area of the substrate 101 to encircle an area where the first semiconductor device 401 is disposed and an area where the second semiconductor devices 500 are disposed. In some embodiments, the adhesive 700 may not form a full ring, and may include a plurality of discrete pieces, in accordance with some embodiments. Alternatively, the adhesive 700 forms a full ring to encircle the first semiconductor device 401 and the second semiconductor devices 500 in accordance with some embodiments. In some embodiments, the adhesive 700 is dispensed on two opposite edges of the top surface S1 of each second semiconductor device 500 as shown in FIG. 9.

Referring to FIG. 12, the substrate 101 may be used to interconnect the first semiconductor device 401 and the second semiconductor devices 500 with other packages and/or devices to form functional circuits. Other packages and/or devices may be multiple passive devices 130, such as capacitors, resistors, inductors, varactors, and/or the like. As shown in FIG. 12, the multiple passive devices 130 are disposed on the substrate 101 and around the periphery of the first semiconductor device 401 in accordance with some embodiments, but the disclosure is not limited thereto.

In some embodiments, the material of the adhesive 700 includes a base material and fillers dispersed in the base material. The base material may be a polymer such as epoxies, urethane, polyurethane, silicone elastomers or the like. The fillers are such as particles made of aluminum oxide, boron nitride, aluminum nitride or the like. The adhesive 700 is dispensed on the second semiconductor devices 500, which consume a relatively low amount of power, and hence generate less heat than the first semiconductor device 401. The adhesive 700 may be dispensed to a pattern of a plurality of strips in accordance with some embodiments. The width and the length of the strips, and the space between the strips of the adhesive 700 are determined by the area size of flange portion 610 and the second semiconductor devices 500.

Then, a ring structure 600 is bonded onto the substrate 101 and the second semiconductor devices 500 through the adhesive 700. In some embodiments, the ring structure 600 has a quadrangular ring-like shape in the plane views such as the top view shown in FIG. 12, the disclosure is not limited thereto. In some alternative embodiments, the pattern of the ring structure 600 may be designed based on the various design. Noted that the ring structure 600 is attached on the substrate 101 and surrounds the first semiconductor device 401 and the second semiconductor devices 500 to constrain the substrate 101 in order to prevent its warpage or other movement relative to the semiconductor package, which may be caused by thermal cycling during package assembly, reliability testing, or field operation. The warpage and stress in the dies or package may lead to die performance degradation or package failure.

In some embodiments, the ring structure 600 is formed of a rigid yet flexible material. In one exemplary embodiment, the ring structure 600 is formed from a metal material with high thermal conductivity (k), such as steel, stainless steel (e.g., SUS 430), copper, aluminum, copper tungsten, nickel-iron alloy (e.g., Alloy 42), the like, or combinations thereof. In another embodiment, the ring structure 600 includes a ceramic material. In yet another embodiment, the ring structure 600 includes a silicon containing material. In yet another embodiment, the ring structure 600 includes a composite alloy. In yet another embodiment, the ring structure 600 includes a plastic material. In the present embodiment, the material of the ring structure 600 is typically selected to have a CTE the same as or sufficiently similar to the substrate 101 in order to apply a counter force to the substrate 101 and reduce the warpage of the semiconductor package to within tolerances accepted in the industry. For example, the CTE of the ring structure 600 is smaller than 25 ppm/° C., such as 17 ppm/° C., and the CTE of the substrate 101 is in a range of 8 ppm/° C. to 25 ppm/° C. In some embodiments, the adhesive 700 for bonding the ring structure 600 to the substrate 101 may include any suitable adhesive, epoxy, die attach film (DAF), or the like. Alternatively, the adhesive 700 may be a thermally conductive material.

In some embodiments, the ring structure 600 may include a wall portion 620 and a flange portion 610 connected to the upper portion of the wall portion 620. The wall portion 620 is bonded to the substrate 101 through the adhesive 700 and surrounds the first semiconductor device 401 and the second semiconductor devices 500. To be more specific, the wall portion 620 surrounds the area where the first semiconductor device 401 and the second semiconductor devices 500 are disposed, and also disposed between the first semiconductor device 401 and the second semiconductor devices 500. The flange portion 610 extended over and bonded to the top surface S1 of the second semiconductor devices 500 through the adhesive 700. The flange portion 610 partially overlaps with top surfaces S1 of the second semiconductor devices 500 from a top view shown in FIG. 12. Accordingly, the adhesive 700 is in contact with a lower surface of the flange portion 610 and the top surfaces S1 of the second semiconductor devices 500, so as to bond the ring structure 600 onto the second semiconductor devices 500 for increasing the bonding strength between the ring structure 600 and the second semiconductor devices 500.

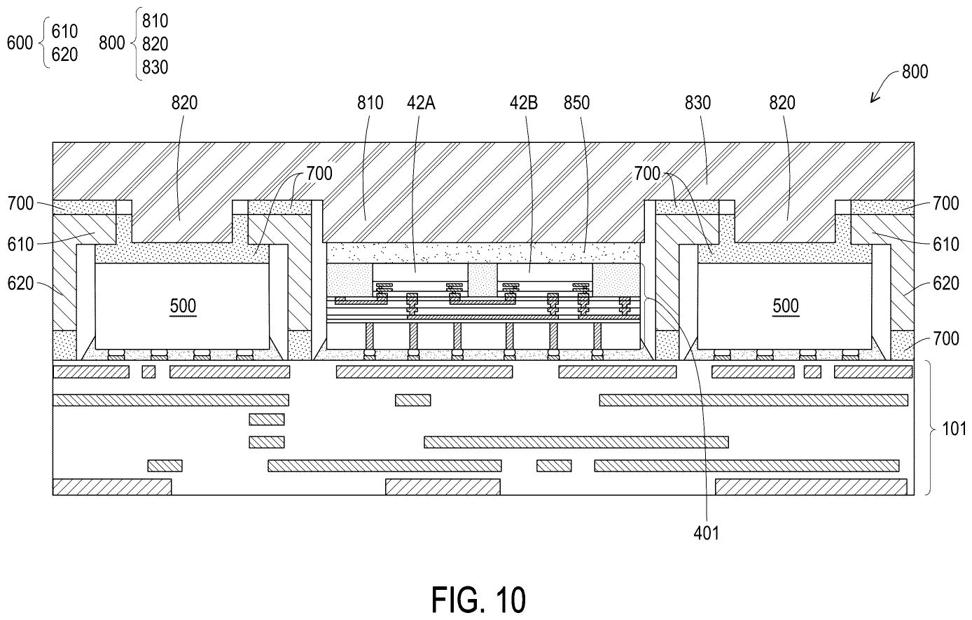

Referring to FIG. 10, in some embodiments, the adhesive 700 may then be further dispensed on an upper surface of the flange portion 610 and the rest of the top surface of the second semiconductor devices 500. In addition, another adhesive 850 is dispensed over the top surface of the first semiconductor device 401. Then, a lid structure 800 covers and is bonded to the first semiconductor device 401, the second semiconductor devices 500 and an upper surface of the flange portion 610. In detail, the lid structure 800 is bonded to the first semiconductor device 401 through the adhesive 850 and bonded to the second semiconductor devices 500 and the upper surface of the flange portion 610 through the adhesive 700.

In some embodiments, the lid structure 800 includes a plate portion 830 and a plurality of bonding portions 810, 820 protruding from the plate portion 830 for being bonded to the first semiconductor device 401 and the second semiconductor devices 500. To be more specific, the bonding portions 810, 820 includes first bonding portion 810 and a plurality of second bonding portions 820. The first bonding portion 810 is protruded toward the first semiconductor device 401 for being bonded to the first semiconductor device 401 through the adhesive 850. The second bonding portions 820 are protruded toward the second semiconductor devices 500 respectively. In some embodiments, the flange portion 610 surrounds the second bonding portion 620, and a lower surface of the flange portion 610 may be substantially coplanar with lower surface of the second bonding portion 620. The adhesive 700 disposed on the top surfaces of the second semiconductor devices 500 is in contact with the second bonding portions 620 and the lower surface of the flange portion 610 and filled between a gap between the second bonding portions 620 and the flange portion 610. The adhesive 850 is in contact with the lower surface of the first bonding portion 810 and the top surface of the first semiconductor device 401.

In some embodiments, the adhesive 700 is disposed between the substrate 101 and the ring structure 600, between the top surfaces of the second semiconductor devices 500 and the lid structure 800, and between an upper surface of the flange portion 610 and the lid structure 800 for bonding the ring structure 600 to the substrate 101, bonding the flange portion 610 to the second semiconductor devices 500, bonding the flange portion 610 to the second semiconductor devices 500 and the lid structure 800, and for bonding the lid structure 800 to the second semiconductor devices 500. The adhesive 700 is dispensed on the second semiconductor devices 500, which consume a relatively low amount of power, and hence generate less heat than the first semiconductor device 401. The material of the adhesive 700 includes a base material and fillers dispersed in the base material. The base material may be a polymer such as epoxies, urethane, polyurethane, silicone elastomers or the like. The fillers are such as particles made of aluminum oxide, boron nitride, aluminum nitride or the like.

In some embodiments, the adhesive 850 may be a thermal interface material (TIM) 850 and is dispensed on the first semiconductor device 401, which consumes a relatively high amount of power, and hence generate a relatively large amount of heat, compared to the second semiconductor devices 500. The thermal interface material 850 on the first semiconductor device 401 has a thermal conductivity that is higher than the thermal conductivity of the adhesive 700 on the second semiconductor devices 500. In some examples, the thermal conductivity of the adhesive 700 is in a range from about 0.5 W/mK to about 2 W/mK. The thermal conductivity of the thermal interface material 850 is in a range from about 10 W/mK to about 50 W/mK. The adhesion of the adhesive 700 is higher than the adhesion of the thermal interface material 850 to enhance the bonding strength between the ring structure 600 and the substrate 101, between the ring structure 600 and the second semiconductor devices 500, and between the lid structure 800 and the second semiconductor devices 500 so as to reduce the risk of delamination. The adhesive 700 may also be a thermal interface material but with lower thermal conductivity and higher adhesion than the thermal interface material 850.

In some embodiments, the material of the thermal interface material 850 includes a base material and thermal conductive fillers dispersed in the base material. The base material includes a polymer such as silicone resin, epoxy resin or the like, which has a good thermal conductivity in a range from about 3 watts per meter kelvin (W/mK) to about 5 W/mK. The thermal conductive fillers in the thermal interface material 850 include particles made of aluminum oxide, boron nitride, aluminum nitride, aluminum, copper, silver, indium, nickel or a combination thereof. In other embodiments, the thermal interface material 850 includes other materials such as a metallic-based or solder-based material containing silver, indium paste, or the like.

In some embodiments, the lid structure 800 may be made of a metal or a metal alloy, for example Al, Cu, Ni, Co, alloy thereof, or a combination thereof. In some instances, the ring structure 600 may be made of a thermal conductive material that is different from the material of the lid structure 800. The material of the ring structure 600 is for example silicon carbide, aluminum nitride, graphite, and the like. In some embodiments, a coefficient of thermal expansion (CTE) of the ring structure 600 is smaller than a CTE of the lid structure 800. Accordingly, the thermal stress caused by thermal cycling during process can be concentrated around the bonding interface of the ring structure 600 (with lower CTE) instead of concentrated in and around the first semiconductor device 401, i.e., high-power consuming device. Therefore, the configuration of the ring structure 600 with lower CTE can release the stress concentration around the first semiconductor device 401 and reduce risk of die cracks or package failure. However, the stress concentration around the bonding interface of the ring structure 600 may cause delamination of the ring structure 600 from the second semiconductor devices 500 and/or the lid structure 800. This delamination can damage or even destroy the semiconductor package during the manufacturing process or else during its intended use. As such, with configuration of adhesive 700 with higher adhesion and the flange portion 610 of the ring structure 600 for increasing contact area with the adhesive 700, the bonding strength between the ring structure 600 and the second semiconductor devices 500 and between the ring structure 600 and the lid structure 800 is enhanced, so as to avoid delamination caused by the stress concentration around the bonding interface of the ring structure 600.

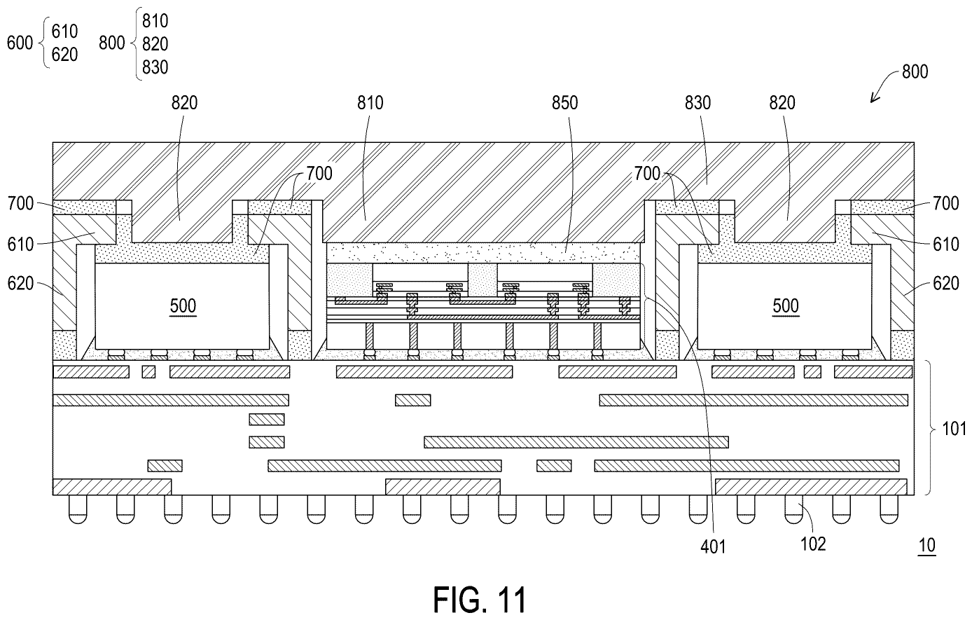

Then, referring to FIG. 11, a plurality of conductive connectors 102 are then formed over a lower surface of the substrate 101. Each of the conductive connectors 102 may be electrically connected to one of the exposed contact pads (not shown) of the substrate 101. The conductive connectors 102 enable electrical connection between the semiconductor package 10 and an external electronic device such as a PCB (not shown). The conductive connectors 102 may be or include solder bumps such as tin-containing solder bumps. The tin-containing solder bumps may further include copper, silver, gold, aluminum, lead, one or more other suitable materials, or a combination thereof. In some embodiments, the tin-containing solder bump is lead-free.

In some embodiments, solder balls (or solder elements) are disposed on the contact pads on the lower surface of the substrate 101. A reflow process is then carried out to melt the solder balls into the conductive connectors 102. In some other embodiments, under bump metallization (UBM) elements are formed over the exposed contact pads before the solder balls are disposed. In some other embodiments, solder elements are electroplated onto the exposed contact pads. Afterwards, a reflow process is used to melt the solder element to form the conductive connectors 102. Accordingly, the semiconductor package 10 shown in FIG. 11 is formed.

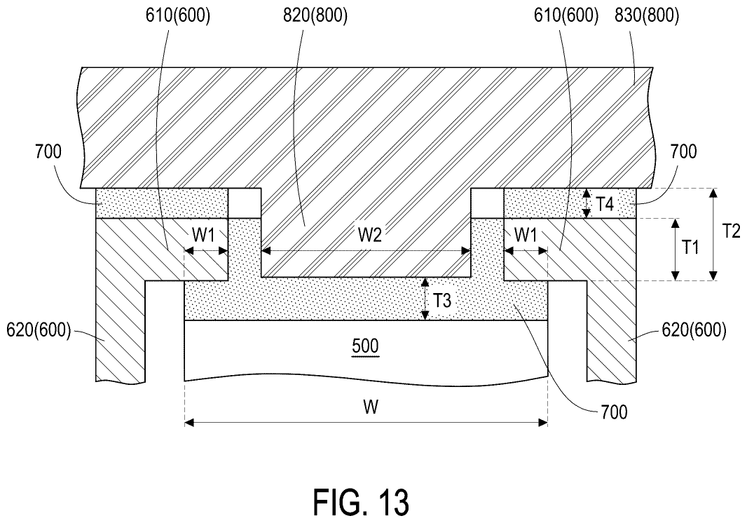

FIG. 13 illustrates a partial enlarged view of the semiconductor package according to some embodiments of the present disclosure. Referring to FIG. 11 and FIG. 13, in some embodiments, to optimize the bonding strength between the ring structure 600, the second semiconductor devices 500, and the lid structure 800 while maintaining desirable amount of stress relief, the dimensions of the ring structure 600 and the lid structure 800 may be specifically designed. For example, a thickness T2 of the second bonding portion 820 is greater than a thickness T1 of the flange portion 610. A width W of one of the second semiconductor devices 500 is greater than a width W2 of the second bonding portion 820. The width W of the second semiconductor device 500 is substantially equal to or greater than twice a width W1 of the flange portion 610 that overlaps the second semiconductor device 500 (i.e., W≥2W1). A gap T4 between the upper surface of the flange portion 610 and lower surface of the plate portion 830 is greater than zero and smaller than or substantially equal to 500 μm. A gap T3 between the lower surface of the second bonding portion 820 and top surface of the second semiconductor device 500 is greater than zero and smaller than or substantially equal to 500 μm.

The recitation of a particular numerical value or value range herein is understood to include or be a recitation of an approximate numerical value or value range (e.g., within +/−20%, +/−10%, or +/−5%). Similarly, the recitation of equivalence, essential equivalence, or approximate equivalence is understood to encompass actual equality as well as essential or approximate equivalence (e.g., identical to within +/−20%, +/−10%, or +/−5%).

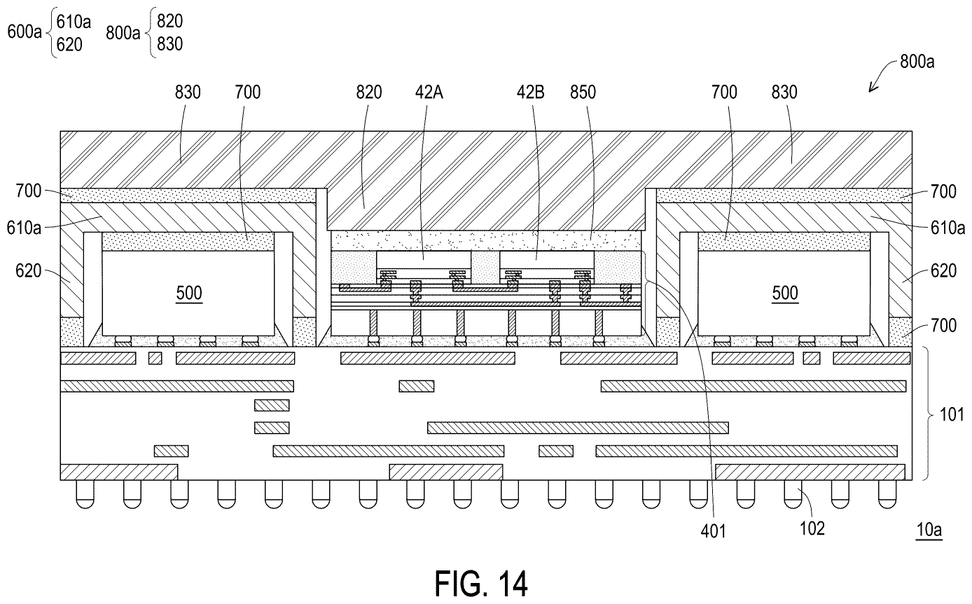

FIG. 14 illustrates a schematic cross sectional view of the semiconductor package according to some embodiments of the present disclosure. It is noted that the semiconductor package 10a shown in FIG. 14 contains many features same as or similar to the semiconductor package disclosed in the previous embodiments. For purpose of clarity and simplicity, detail description of same or similar features may be omitted, and the same or similar reference numbers denote the same or like components.

Referring to FIG. 14, in the present embodiment, the ring structure 600a includes a wall portion 620 and the flange portion 610a. The wall portion 620 surrounds the first semiconductor device 401 and the second semiconductor devices 500, and the flange portion 610a extended across a top surface of at least one second semiconductor devices 500 for connecting the wall portion 620 on two opposite sides of the second semiconductor devices 500. In some embodiments, the flange portion 610a may completely cover the top surfaces of the second semiconductor devices 500. In other embodiments, the flange portion 610a may not completely cover the top surfaces of the second semiconductor devices 500, but have some cutouts for partially revealing the top surfaces of the second semiconductor devices 500. In this embodiment, a part of the flange portion 610a is extended across a top surface of the second semiconductor device 500 and connects the wall portion 620 on two opposite sides of the second semiconductor device 500.

With such configuration, the lid structure 800a may not include the second bonding portion protruding toward the second semiconductor device 500, but simply bonding to the second semiconductor device 500 with the planar plate portion 830. The adhesive 700 is comprehensively dispensed between the flange portion 610a and the second semiconductor device 500, and between the flange portion 610a and the lid structure 800a. As such, with configuration of the flange portion 610a extended across the top surface of the second semiconductor device 500 for increasing contact area with the adhesive 700, the bonding strength between the ring structure 600a and the second semiconductor devices 500 and between the ring structure 600a and the lid structure 800a is enhanced, so as to avoid delamination caused by the stress concentration around the bonding interface of the ring structure 600a.

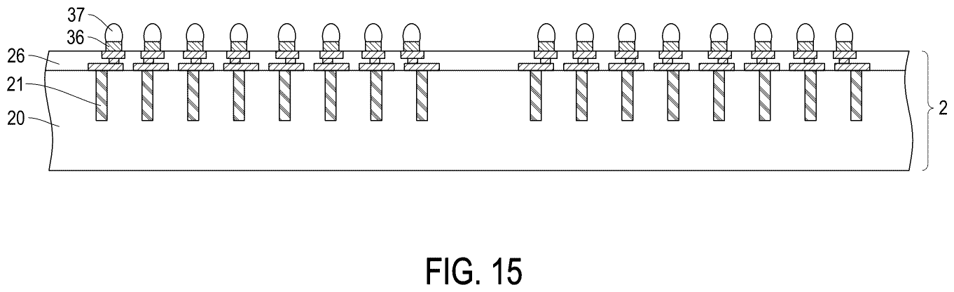

FIG. 15 to FIG. 22 illustrate cross sectional views of intermediate stages in the manufacturing of a semiconductor package according to some embodiments of the present disclosure. It is noted that manufacturing method and structure of the semiconductor package 10b shown in FIG. 15 to FIG. 22 contains many features same as or similar to the manufacturing methods and structures of the semiconductor packages disclosed in the previous embodiments. For purpose of clarity and simplicity, detail description of same or similar features may be omitted, and the same or similar reference numbers denote the same or like components.

In accordance with some embodiments of the disclosure, configurations of ring structures, adhesives, and the lid structures in the disclosure not only can be applied in a semiconductor package such as a System on Integrate Chip (SoIC) package as it is shown above, but also can be applied to other suitable packages that suffers thermal stress caused by CTS mismatch amount components in packages. FIG. 15 to FIG. 22 illustrate one of the possible packages such as a Chip on Wafer on Substrate (CoWoS) that can adopt such configurations.

FIG. 15 illustrates the formation of a first side of a wafer 2. As illustrated in FIG. 15, the wafer 2 may be an interposer or another die. The wafer 2 includes a substrate 20, which is in a wafer form. The substrate 20 may include a bulk semiconductor substrate, SOI substrate, multi-layered semiconductor substrate, or the like. The semiconductor material of the substrate 20 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 20 may be doped or undoped. Devices, such as transistors, capacitors, resistors, diodes, and the like, may be formed in and/or on an upper surface, which may also be referred to as an active surface, of the substrate 20. In embodiments where the wafer 2 is an interposer wafer, the wafer 2 will generally not include active devices therein, although the interposer may include passive devices formed in and/or on the substrate 20 and/or in redistribution structure 26.

A plurality of through vias 21 are formed to extend from the upper surface of substrate 20 into substrate 20. The through vias 21 are also sometimes referred to as through-substrate vias or through-silicon vias when substrate 20 is a silicon substrate. The through vias 21 may be formed by forming recesses in the substrate 20 by, for example, etching, milling, laser techniques, a combination thereof, and/or the like. A thin dielectric material may be formed in the recesses, such as by using an oxidation technique. A thin barrier layer may be conformally deposited over the front side of the substrate 20 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 20 by, for example, CMP. Thus, the through vias 21 may comprise a conductive material and a thin barrier layer between the conductive material and the substrate 20.

Then, a redistribution structure 26 is formed over the surface of the substrate 20, and is used to electrically connect the integrated circuit devices, if any, and/or through vias 21 together and/or to external devices. The redistribution structure 26 may include one or more dielectric layer(s) and respective metallization pattern(s) in the dielectric layer(s). The metallization patterns may comprise vias and/or traces to interconnect any devices and/or through vias 21 together and/or to an external device. The metallization patterns are sometimes referred to as Redistribution Lines (RDL). The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. A metallization pattern may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVD, or the like. Any excessive diffusion barrier layer and/or conductive material on the dielectric layer may be removed, such as by using a CMP.

Then, a plurality of electrical connectors 36/37 are formed at the top surface of the redistribution structure 26 on conductive pads. In some embodiments, the conductive pads include under bump metallurgies (UBMs). In the illustrated embodiment, the pads are formed in openings of the dielectric layers of the redistribution structure 26. In another embodiment, the pads (UBMs) can extend through an opening of a dielectric layer of the redistribution structure 26 and also extend across the top surface of the redistribution structure 26. As an example to form the pads, a seed layer (not shown) is formed at least in the opening in the dielectric layer of the redistribution structure 26. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photo resist is then formed and patterned on the seed layer. The photo resist may be formed by spin coating or the like and may be exposed to light for patterning. The pattern of the photo resist corresponds to the pads. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may comprise a metal, like copper, titanium, tungsten, aluminum, or the like. Then, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form the pads. In the embodiment, where the pads are formed differently, more photo resist and patterning steps may be utilized.

In some embodiments, the electrical connectors 36/37 include a metal pillar 36 with a metal cap layer 37, which may be a solder cap 37, over the metal pillar 36. The electrical connectors 36/37 including the pillar 36 and the cap layer 37 are sometimes referred to as micro bumps 36/37. In some embodiments, the metal pillars 36 include a conductive material such as copper, aluminum, gold, nickel, palladium, the like, or a combination thereof and may be formed by sputtering, printing, electro plating, electroless plating, CVD, or the like. The metal pillars 36 may be solder free and have substantially vertical sidewalls. In some embodiments, a metal cap layer 37 is formed on the top of the metal pillar 36. The metal cap layer 37 may include nickel, tin, tin-lead, gold, copper, silver, palladium, indium, nickel-palladium-gold, nickel-gold, the like, or a combination thereof and may be formed by a plating process.

In another embodiment, the electrical connectors 36/37 do not include the metal pillars and are solder balls and/or bumps, such as controlled collapse chip connection (C4), electroless nickel immersion Gold (ENIG), electroless nickel electroless palladium immersion gold technique (ENEPIG) formed bumps, or the like. In this embodiment, the bump electrical connectors 36/37 may include a conductive material such as solder, copper, aluminum, gold, nickel, silver, palladium, tin, the like, or a combination thereof. In this embodiment, the electrical connectors 36/37 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes.

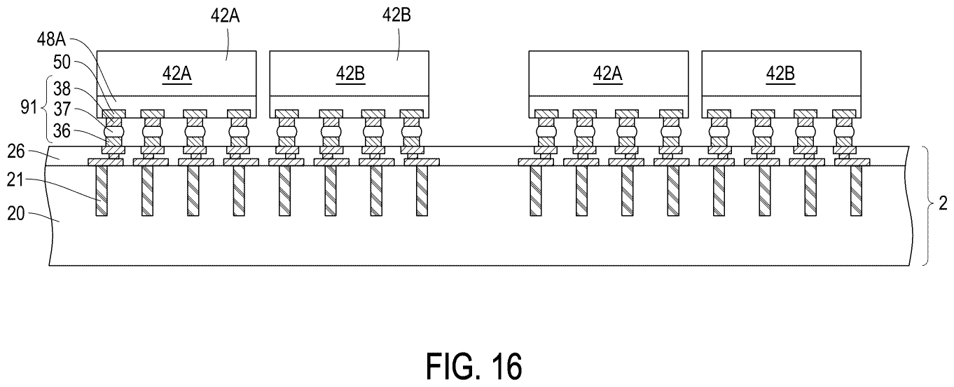

In FIG. 16, the device dies 42A, and the device die 42B are attached to the first side of the wafer 2, for example, through flip-chip bonding by way of the electrical connectors 36/37 and the metal pillars 38 on the dies to form conductive joints 91. The metal pillars 38 may be similar to the metal pillars 36 and the description is not repeated herein. The device dies 42A, 42B may be placed on the electrical connectors 36/37 using, for example, a pick-and-place tool. In some embodiments, the metal cap layers 37 are formed on the metal pillars 36 (as shown in FIG. 3), the metal pillars 38 of the device dies 42A and 42B, or both.

The device dies 42A may be formed through similar processing as described above in reference to the device dies 42B. In some embodiments, the device dies 42A include one or more memory dies, such as a stack of memory dies (e.g., DRAM dies, SRAM dies, High-Bandwidth Memory (HBM) dies, Hybrid Memory Cubes (HMC) dies, or the like). In the stack of memory dies embodiments, a device die 42A can include both memory dies and a memory controller, such as, for example, a stack of four or eight memory dies with a memory controller. Also, in some embodiments, the device dies 42A may be different sizes (e.g., different heights and/or surface areas), and in other embodiments, the dies 88 may be the same size (e.g., same heights and/or surface areas).

The device dies 42A/42B include a main body 44A/44B, an interconnect structure 48A/48C, and die connectors 50. The main body 44A/44B of the device dies 42A/42B may include any number of dies, substrates, transistors, active devices, passive devices, or the like. In an embodiment, the main body 44A/44B may include a bulk semiconductor substrate, semiconductor-on-insulator (SOI) substrate, multi-layered semiconductor substrate, or the like. The semiconductor material of the main body 44A/44B may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 44A/44B may be doped or undoped. Devices, such as transistors, capacitors, resistors, diodes, and the like, may be formed in and/or on an active surface.

An interconnect structure 48A/48B including one or more dielectric layer(s) and respective metallization pattern(s) is formed on the active surface. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to perform one or more functions. The functions may include memory structures, processing structures, sensors, amplifiers, power distribution, input/output circuitry, or the like. Additionally, die connectors 50, such as conductive pillars (for example, comprising a metal such as copper), are formed in and/or on the interconnect structure 48A/48B to provide an external electrical connection to the circuitry and devices. In some embodiments, the die connectors 50 protrude from the interconnect structure 84 to form pillar structure to be utilized when bonding the device dies 42A/42B to other structures. One of ordinary skill in the art will appreciate that the above examples are provided for illustrative purposes. Other circuitry may be used as appropriate for a given application.

More particularly, an IMD layer may be formed in the interconnect structure 48A/48B. The IMD layer may be formed, for example, of a low-K dielectric material, such as PSG, BPSG, FSG, SiOxCy, Spin-On-Glass, Spin-On-Polymers, silicon carbon material, compounds thereof, composites thereof, combinations thereof, or the like, by any suitable method known in the art, such as spinning, CVD, PECVD, HDP-CVD, or the like. A metallization pattern may be formed in the IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by ALD, or the like. The conductive material of the metallization patterns may comprise copper, aluminum, tungsten, silver, and combinations thereof, or the like, deposited by CVD, PVD, or the like. Any excessive diffusion barrier layer and/or conductive material on the IMD layer may be removed, such as by using a CMP.

In the embodiments wherein the die connectors 50 protrude from the interconnect structures 48A/48B, respectively, the metal pillars 38 may be excluded from the device dies 42A/42B as the protruding die connectors 50 may be used as the pillars for the metal cap layers 37.

The conductive joints 91 electrically couple the circuits in the device dies 42A and the device dies 42B through the interconnect structures 48A and 48B and the die connectors 50, respectively, to the redistribution structure 26 and through vias 21 in the wafer 2.

In some embodiments, before bonding the electrical connectors 36/37, the electrical connectors 36/37 are coated with a flux (not shown), such as a no-clean flux. The electrical connectors 36/37 may be dipped in the flux or the flux may be jetted onto the electrical connectors 36/37. In another embodiment, the flux may be applied to the electrical connectors 38/37. In some embodiments, the electrical connectors 36/37 and/38/37 may have an epoxy flux (not shown) formed thereon before they are reflowed with at least some of the epoxy portion of the epoxy flux remaining after the device dies 42A and the device dies 42B are attached to the wafer 2. This remaining epoxy portion may act as an underfill to reduce stress and protect the joints resulting from the reflowing the electrical connectors 36/37/38.

In an embodiment, the device dies 42A and 42B are bonded to the interposer wafer 2 by a reflow process. During this reflow process, the electrical connectors 36/37/38 are in contact with the device dies 42A and 42B, respectively, and the pads of the redistribution structure 26 to physically and electrically couple the device dies 42A and 42B to the wafer 2. After the bonding process, an IMC (not shown) may form at the interface of the metal pillars 36 and 38 and the metal cap layers 37.

In some embodiments, device die 42B may be a system-on-a-chip (SoC) or a graphics processing unit (GPU) and the second dies are memory dies that may utilized by the dies 68. In an embodiment, the device dies 42A are stacked memory dies. For example, the stacked memory dies 42A may include low-power (LP) double data rate (DDR) memory modules, such as LPDDR1, LPDDR2, LPDDR3, LPDDR4, or the like memory modules.

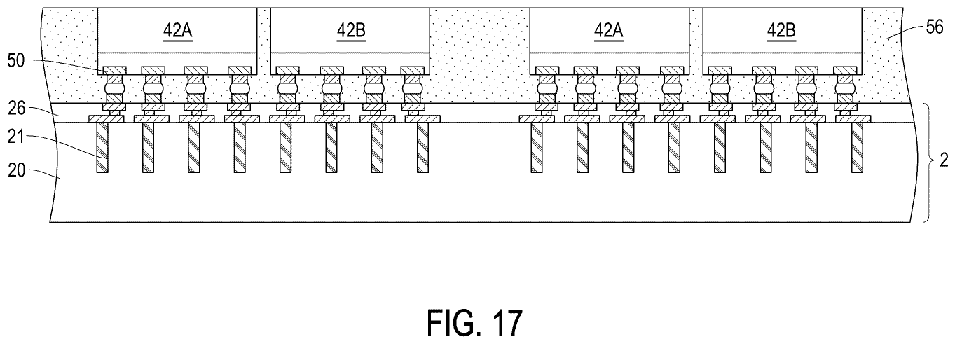

In FIG. 17, an encapsulating material 56 is formed on the various components. The encapsulating material 56 may be a molding compound, epoxy, or the like, and may be applied by compression molding, transfer molding, or the like. A curing step is performed to cure the encapsulating material 56, wherein the curing may be a thermal curing, a Ultra-Violet (UV) curing, or the like. In some embodiments, the device dies 42A, 42B are buried in the encapsulating material 56, and after the curing of the encapsulating material 56, a planarization step, such as a grinding, may be performed to remove excess portions of the encapsulating material 56, which excess portions are over top surfaces of the device dies 42A, 42B. Accordingly, top surfaces of the device dies 42A, 42B are exposed, and are level with a top surface of the encapsulating material 56.

In some embodiments, an underfill material may be optionally dispensed into the gaps between the device dies 42A, 42B and the redistribution structure 26, and surrounding the conductive joints 91 before the encapsulating material 56 is formed. The underfill material may extend up along sidewall of the device dies 42A, 42B. The underfill material may be any acceptable material, such as a polymer, epoxy, molding underfill, or the like. The underfill material may be formed by a capillary flow process after the device dies 42A, 42B are attached, or may be formed by a suitable deposition method before the device dies 42A, 42B are attached.

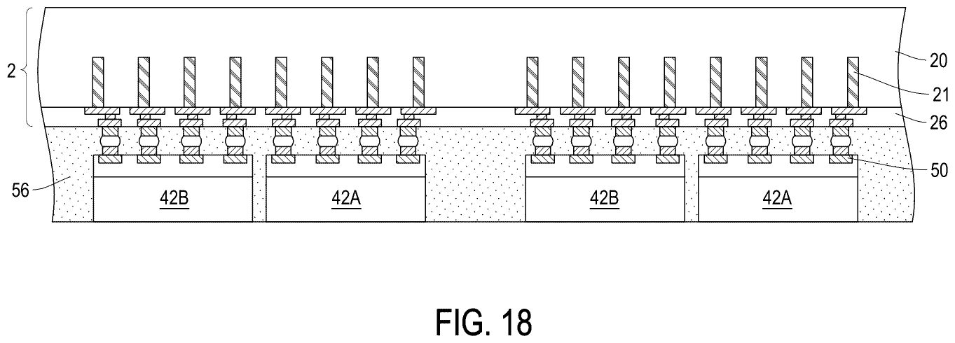

FIG. 18 through FIG. 20 illustrate the formation of the second side of the wafer 2. In FIG. 18, the structure of FIG. 17 is flipped over to prepare for the formation of the second side of the wafer 2. Although not shown, the structure may be placed on a carrier or support structure for the process of FIG. 18 through FIG. 20.

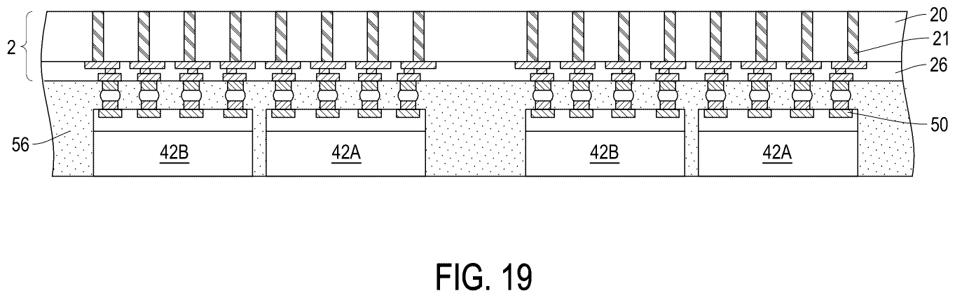

In FIG. 19, a thinning process is performed on the second side of the substrate 20 to thin the substrate 20 until the through vias 21 are exposed. The thinning process may include an etching process, a grinding process, the like, or a combination thereof.

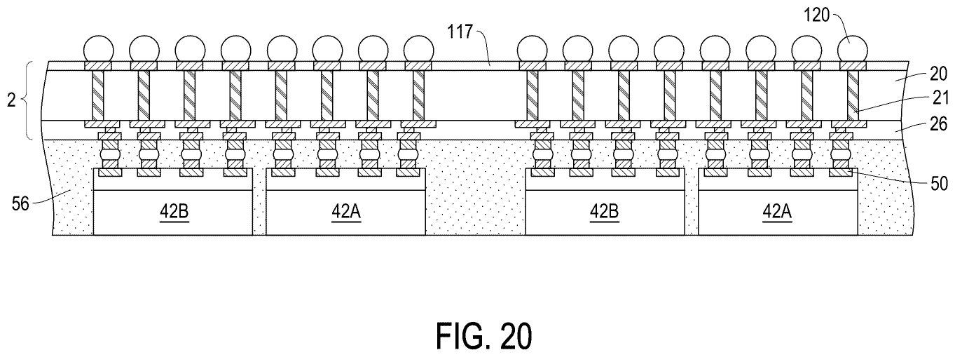

In FIG. 20, a redistribution structure 117 is formed on the second side of the substrate 20, and is used to electrically connect the through vias 21 together and/or to external devices. The redistribution structure 117 includes one or more dielectric layers and metallization patterns in the one or more dielectric layers. The metallization patterns may comprise vias and/or traces to interconnect through vias 21 together and/or to an external device. The metallization patterns are sometimes referred to as Redistribution Lines (RDLs). The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. The metallization patterns may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVC, or the like. Any excessive diffusion barrier layer and/or conductive material on the dielectric layer may be removed, such as by using a CMP.

Then, a plurality of conductive connectors 120 are also formed the metallization patterns of the redistribution structure 117 and are electrically coupled to the through vias 21. The conductive connectors 120 are formed at the top surface of the redistribution structure 117. In some embodiments, the redistribution structure 117 include UBMs. In the illustrated embodiment, the pads are formed in openings of the dielectric layer of the redistribution structure 117. In another embodiment, the pads (UBMs) can extend through an opening of a dielectric layer of the redistribution structure 117 and also extend across the top surface of the redistribution structure 117.

In some embodiments, the conductive connectors 120 are solder balls and/or bumps, such as ball grid array (BGA) balls, C4 micro bumps, ENIG formed bumps, ENEPIG formed bumps, or the like. The conductive connectors 120 may include a conductive material such as solder, copper, aluminum, gold, nickel, silver, palladium, tin, the like, or a combination thereof. In some embodiments, the conductive connectors 120 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 120 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 120. The metal cap layer may include nickel, tin, tin-lead, gold, silver, palladium, indium, nickel-palladium-gold, nickel-gold, the like, or a combination thereof and may be formed by a plating process.

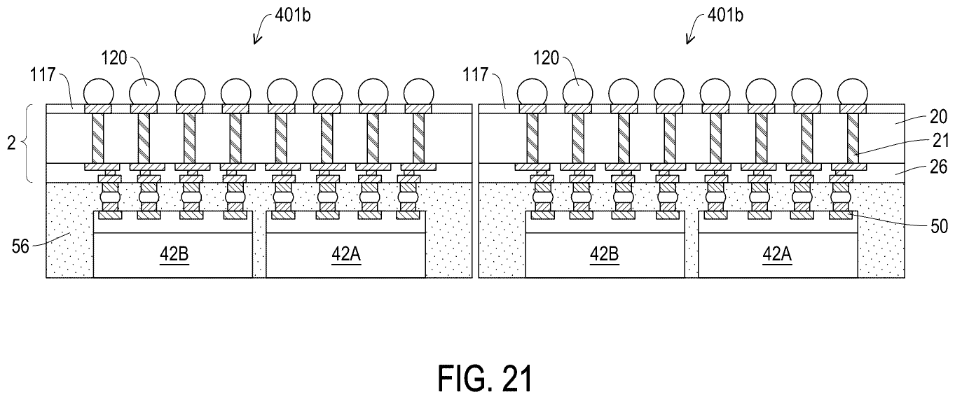

Then, referring to FIG. 21, a singulation (die-saw) process is performed on the resulting structure shown in FIG. 20 to separate the resulting structure into a plurality of first semiconductor devices 401b. The singulation process may include sawing, dicing, or the like. To be more specific, the singulation process is performed on the encapsulating material 56 and the wafer 2 to separate the composite wafer into a plurality of first semiconductor devices (package structures) 401b. After the singulation process, the interposer 2 is singulated from the interposer wafer, and the device dies 42A, 42B are bonded to the interposer 2 through flip chip bonding.

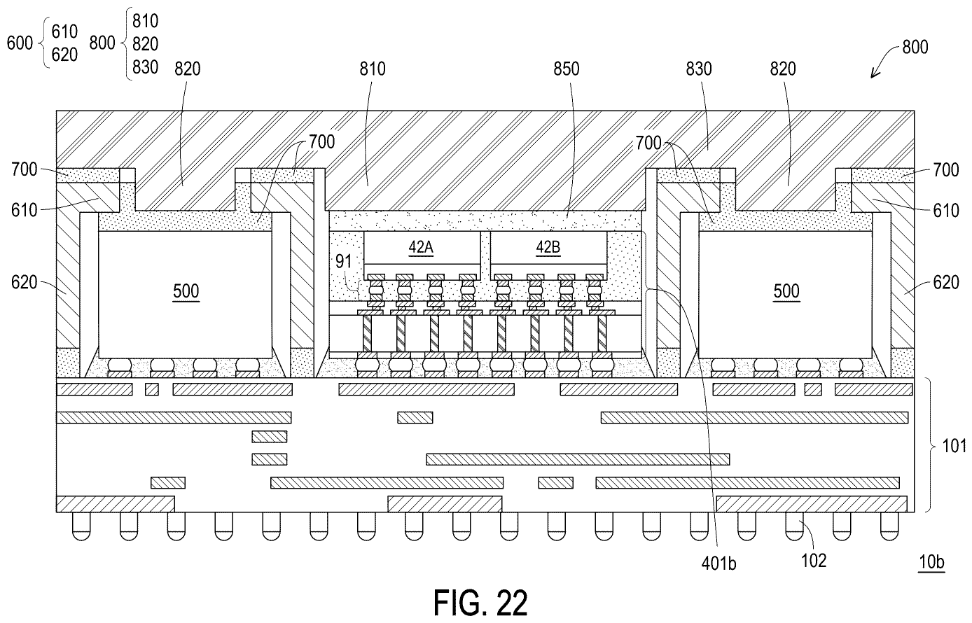

Referring to FIG. 21 and FIG. 22, then, one of the first semiconductor devices 401b is picked and placed over the substrate 101, and the first semiconductor device 401b is bonded to the substrate 101 through, for example, flip chip bonding. The conductive connectors 120 are aligned to, and are put against, the bond pads of the substrate 101. The conductive connectors 120 may be reflowed to create a bond between the substrate 101 and the semiconductor device 401b. The substrate 101 may include a package substrate, such as a build-up substrate including a core therein, a laminate substrate including a plurality of laminated dielectric films, a PCB, or the like. The substrate 101 may include electrical connectors (not shown), such as solder balls, opposite the component package to allow the substrate 101 to be mounted to another device.

Then, the processes as illustrated in FIG. 8 to FIG. 11 can be applied herein and form the semiconductor package 10b shown in FIG. 22. Accordingly, the configuration of the ring structure 600 can release the stress concentration around the first semiconductor device 401b and reduce risk of die cracks or package failure. In addition, with configuration of the flange portion 610 of the ring structure 600 for increasing contact area with the adhesive 700, the bonding strength between the ring structure 600 and the second semiconductor devices 500 and between the ring structure 600 and the lid structure 800 is enhanced, so as to avoid delamination caused by the stress concentration around the bonding interface of the ring structure 600.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a substrate, a first semiconductor device disposed over the substrate, a plurality of second semiconductor devices disposed over the substrate and around the first semiconductor device, a ring structure disposed over the substrate, and a lid structure. The ring structure surrounds the first semiconductor device and the plurality of second semiconductor devices, and disposed between the first semiconductor device and the plurality of second semiconductor devices, the ring structure includes a flange portion partially overlap with top surfaces of the plurality of second semiconductor devices from a top view. The lid structure covers and is bonded to the first semiconductor device, the plurality of second semiconductor devices and an upper surface of the flange portion. In one embodiment, the semiconductor package further includes a first adhesive disposed between the lid structure and the first semiconductor device, and a second adhesive disposed between the lid structure and the second semiconductor device and between the lid structure and the upper surface of the flange portion. In one embodiment, a thermal conductivity of the first adhesive is higher than a thermal conductivity of the second adhesive, and an adhesion of the second adhesive is higher than an adhesion of the first adhesive. In one embodiment, a coefficient of thermal expansion (CTE) of the ring structure is smaller than a CTE of the lid structure. In one embodiment, the lid structure comprises a first bonding portion protruded toward the first semiconductor device for bonded to the first semiconductor device. In one embodiment, the lid structure comprises a second bonding portion protruded toward the plurality of second semiconductor devices, wherein the flange portion surrounds the second bonding portion. In one embodiment, a thickness of the second bonding portion is greater than a thickness of the flange portion. In one embodiment, a width of one of the plurality of second semiconductor devices is greater than a width of the second bonding portion. In one embodiment, a width of one of the plurality of second semiconductor devices is substantially equal to or greater than twice a width of the flange portion that overlaps the one of the plurality of second semiconductor devices.

In accordance with some embodiments of the disclosure, a semiconductor package includes a substrate, a package structure disposed over the substrate, a plurality of die stacks disposed over the substrate and arranged on two opposite sides of the package structure, a ring structure, a lid structure, and an adhesive. The ring structure is disposed over the substrate and surrounding the package structure and the plurality of die stacks. The ring structure includes a flange portion extended over top surfaces of the plurality of die stacks. The lid structure covers and is bonded to the package structure, the plurality of die stacks and the ring structure. The adhesive is bonded between a lower surface of the flange portion and the top surfaces of the plurality of die stacks. In one embodiment, the semiconductor package further includes a thermal interface material bonded between an upper surface of the package structure and the lid structure. In one embodiment, the adhesive is disposed between the top surfaces of the plurality of die stacks and the lid structure, and between an upper surface of the flange portion and the lid structure. In one embodiment, the package structure includes a lower die disposed over the substrate, a plurality of upper dies disposed over the lower die, and an encapsulating material disposed over the lower die and laterally encapsulating the plurality of upper dies. In one embodiment, the plurality of upper dies comprises a plurality of upper pads in direct contact with a plurality of lower pads of the lower die respectively. In one embodiment, the lid structure includes a plate portion and a plurality of bonding portions protruding from the plate portion for being bonded to the package structure and the plurality of die stacks, and the adhesive disposed on the top surfaces of the plurality of die stacks is in contact with the plurality of bonding portions and the lower surface of the flange portion. In one embodiment, the ring structure further includes a wall portion surrounding package structure and the plurality of die stacks, and the flange portion extended across a top surface of one of the plurality of die stacks for connecting the wall portion on two opposite sides of the one of the plurality of die stacks.

In accordance with some embodiments of the disclosure, a method of manufacturing a semiconductor package includes: providing a first semiconductor device over a substrate; providing a plurality of second semiconductor devices over the substrate; providing an adhesive on the substrate and top surfaces of the plurality of second semiconductor devices; bonding a ring structure over the substrate and the plurality of second semiconductor devices through the adhesive, wherein the ring structure surrounds the first semiconductor device and the plurality of second semiconductor devices and comprises a flange portion extended over and bonded to the top surfaces of the plurality of second semiconductor devices; and bonding a lid structure over the first semiconductor device, the plurality of second semiconductor devices, and an upper surface of the flange portion. In one embodiment, providing the first semiconductor device over the substrate further includes: bonding a plurality of first dies to a wafer; forming an encapsulating material over the wafer, wherein the encapsulating material at least laterally encapsulates the plurality of first dies; performing a singulation process over the encapsulating material and the wafer to form the first semiconductor device; and bonding the first semiconductor device to the substrate. In one embodiment, the method of bonding the plurality of first dies to the wafer comprises fusion bonding and direct metal bonding. In one embodiment, bonding the lid structure over the first semiconductor device, the plurality of second semiconductor devices, and the upper surface of the flange portion further includes: providing a thermal interface material over the first semiconductor device; providing the adhesive over the upper surface of the flange portion; and bonding the lid structure to the first semiconductor device through the thermal interface material and bonding the lid structure to the plurality of second semiconductor devices and the upper surface of the flange portion through the adhesive.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a first semiconductor device disposed over the substrate;
a plurality of second semiconductor devices disposed over the substrate and around the first semiconductor device;
a ring structure disposed over the substrate, wherein the ring structure surrounds the first semiconductor device and the plurality of second semiconductor devices, and disposed between the first semiconductor device and the plurality of second semiconductor devices, the ring structure comprises a flange portion partially overlap with top surfaces of the plurality of second semiconductor devices from a top view; and
a lid structure covering and bonded to the first semiconductor device, the plurality of second semiconductor devices and an upper surface of the flange portion.

2. The semiconductor package as claimed in claim 1, further comprising a first adhesive disposed between the lid structure and the first semiconductor device, and a second adhesive disposed between the lid structure and the second semiconductor device and between the lid structure and the upper surface of the flange portion.

3. The semiconductor package as claimed in claim 2, wherein a thermal conductivity of the first adhesive is higher than a thermal conductivity of the second adhesive, and an adhesion of the second adhesive is higher than an adhesion of the first adhesive.

4. The semiconductor package as claimed in claim 1, wherein a coefficient of thermal expansion (CTE) of the ring structure is smaller than a CTE of the lid structure.

5. The semiconductor package as claimed in claim 1, wherein the lid structure comprises a first bonding portion protruded toward the first semiconductor device for bonded to the first semiconductor device.

6. The semiconductor package as claimed in claim 1, wherein the lid structure comprises a second bonding portion protruded toward the plurality of second semiconductor devices, wherein the flange portion surrounds the second bonding portion.

7. The semiconductor package as claimed in claim 6, wherein a thickness of the second bonding portion is greater than a thickness of the flange portion.

8. The semiconductor package as claimed in claim 6, wherein a width of one of the plurality of second semiconductor devices is greater than a width of the second bonding portion.

9. The semiconductor package as claimed in claim 1, wherein a width of one of the plurality of second semiconductor devices is substantially equal to or greater than twice a width of the flange portion that overlaps the one of the plurality of second semiconductor devices.

10. A semiconductor package, comprising:
a substrate;
a package structure disposed over the substrate;
a plurality of die stacks disposed over the substrate and arranged on two opposite sides of the package structure;
a ring structure disposed over the substrate and surrounding the package structure and the plurality of die stacks, wherein the ring structure comprises a flange portion extended over top surfaces of the plurality of die stacks;
a lid structure covering and bonded to the package structure, the plurality of die stacks and the ring structure; and
an adhesive bonded between a lower surface of the flange portion and the top surfaces of the plurality of die stacks.

11. The semiconductor package as claimed in claim 10, further comprising a thermal interface material bonded between an upper surface of the package structure and the lid structure.

12. The semiconductor package as claimed in claim 10, wherein the adhesive is disposed between the top surfaces of the plurality of die stacks and the lid structure, and between an upper surface of the flange portion and the lid structure.

13. The semiconductor package as claimed in claim 10, wherein the package structure comprises a lower die disposed over the substrate, a plurality of upper dies disposed over the lower die, and an encapsulating material disposed over the lower die and laterally encapsulating the plurality of upper dies.

14. The semiconductor package as claimed in claim 10, wherein the plurality of upper dies comprises a plurality of upper pads in direct contact with a plurality of lower pads of the lower die respectively.

15. The semiconductor package as claimed in claim 10, wherein the lid structure comprises a plate portion and a plurality of bonding portions protruding from the plate portion for being bonded to the package structure and the plurality of die stacks, and the adhesive disposed on the top surfaces of the plurality of die stacks is in contact with the plurality of bonding portions and the lower surface of the flange portion.

16. The semiconductor package as claimed in claim 10, wherein the ring structure further comprises a wall portion surrounding package structure and the plurality of die stacks, and the flange portion extended across a top surface of one of the plurality of die stacks for connecting the wall portion on two opposite sides of the one of the plurality of die stacks.

17. A method of manufacturing a semiconductor package, comprising:
providing a first semiconductor device over a substrate;
providing a plurality of second semiconductor devices over the substrate;
providing an adhesive on the substrate and top surfaces of the plurality of second semiconductor devices;
bonding a ring structure over the substrate and the plurality of second semiconductor devices through the adhesive, wherein the ring structure surrounds the first semiconductor device and the plurality of second semiconductor devices and comprises a flange portion extended over and bonded to the top surfaces of the plurality of second semiconductor devices; and
bonding a lid structure over the first semiconductor device, the plurality of second semiconductor devices, and an upper surface of the flange portion.

18. The method as claimed in claim 17, wherein providing the first semiconductor device over the substrate further comprising:
bonding a plurality of first dies to a wafer;
forming an encapsulating material over the wafer, wherein the encapsulating material at least laterally encapsulates the plurality of first dies;
performing a singulation process over the encapsulating material and the wafer to form the first semiconductor device; and
bonding the first semiconductor device to the substrate.

19. The method as claimed in claim 18, wherein the method of bonding the plurality of first dies to the wafer comprises fusion bonding and direct metal bonding.

20. The method as claimed in claim 17, wherein bonding the lid structure over the first semiconductor device, the plurality of second semiconductor devices, and the upper surface of the flange portion further comprising:
providing a thermal interface material over the first semiconductor device;
providing the adhesive over the upper surface of the flange portion; and
bonding the lid structure to the first semiconductor device through the thermal interface material and bonding the lid structure to the plurality of second semiconductor devices and the upper surface of the flange portion through the adhesive.
